(19) United States
(12) Patent Application Publication
(10) Pub. No.: US 2008/0135991 A1
(43) Pub. Date: Jun. 12, 2008

(54) SEMICONDUCTOR DEVICE PACKAGE FEATURING ENCAPSULATED LEADFRAME WITH PROJECTING BUMPS OR BALLS

(75) Inventors: James Harnden, Hollister, CA (US); Richard K. Williams, Cupetino, CA (US); Anthony Chia, Singapore (SG); Teng Hui, Shanghai (CN); Hongbo Yang, Shanghai (CN); Zhou Ming, Shanghai (CN); Anthony C. Tsui, Saratoga, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: GEM Services, Inc., Santa Clara, CA (US)

(21) Appl. No.: 11/609,706

(22) Filed: Dec. 12, 2006

(51) Int. Cl. H01L 23/495; H01L 21/00

(52) U.S. Cl. 257/666; 438/124; 257/E23.031; 257/E21.001

(57) ABSTRACT

Embodiments of the present invention relate to semiconductor device packages featuring encapsulated leadframes in electrical communication with a supported die through electrically conducting bumps or balls. By eliminating the need for a separate diepad and lateral isolation between an edge of the diepad and adjacent non-integral leads or pins, embodiments of packages fabricated by bump on leadframe (BOL) processes in accordance with embodiments of the present invention increase the space available to the die for a given package footprint. Embodiments of the present invention may also permit multiple die and/or multiple passive devices to occupy space in the package previously consumed by the diepad. The result is a flexible packaging process allowing the combination of die and technologies required for complete sub-systems in a conventional small JEDEC specified footprint.

### BACKGROUND OF THE INVENTION

FIG. 1 shows a simplified plan view of a conventional package 100 for housing a semiconductor device. Specifically, semiconductor die 102 is supported on diepad 104 forming a part of leadframe 106. Leadframe 106 also includes leads 108 not integral with the diepad 104 and extending out of the plastic body 110 of package 100 encapsulating leadframe 106. The ends of leads 108 proximate to the diepad 104 comprises a lead bondpad 109 configured to receive an end of a bond wire 114. Bond wire 114 extends from a surface 102a of packaged die 102 to provide electrical contact with non-integral lead 112.

One attribute of the conventional package design shown in FIG. 1 is the efficient utilization of space. In particular, it is desirable that a package occupying a given footprint (i.e. dimensions in the x-y plane) house a die having as large an area as possible. This allows a package to consume as little space as possible, a consideration which may be of particular importance for packages used in portable applications such as laptop computers, cell phones, or personal digital assistants (PDAs).

An alternative technique to the conventional package of FIG. 1 that maximizes the efficient use of space, is “chip scale” attachment directly to a printed circuit board (PCB). This technique utilizes direct mounting of the die onto the leadframe using some form of conductive bump or ball between the die and the copper leadframe. The part is then directly mounted via the balls or bumps, using soft solder reflow, onto copper lands of a printed circuit board (PCB). From this point forward, the die or leadframe having balls or bumps will be referred to as the Bump (or Ball) on Leadframe (BOL) process.

If a bump process is used, the bumps are generally formed on the die while the die are still in wafer form. Bumps are usually formed using metallurgical plating and/or sputtering process employing masks and photo-resist. Bumping of the wafers can be done by the fab that builds the wafers, a third party subcontractor who specializes in post-fab processes, or the subcontractor who does the packaging.

Balls may be present on the leadframe or die, depending on the technology used to form the balls and the assembly sequence. Balls are commonly created after fabrication of the die, utilizing a number of techniques. One technique is to ball bond Gold or Copper wires, and then cut the wire off—which can be done on the die in wafer form, or it can be done on the leadframe in a pattern that matches mirror images the bond pad locations on the die. Alternative techniques for forming balls include solder drop or others collectively known as “balls” because all are common in the industry and have specific application for this process.

Despite its size efficiency, the “chip-scale” approach may offer certain disadvantages. One is that the die has no physical or hermetic protection beyond the natural protections built into or deposited onto the silicon. Current chip scale processes do employ a ball or bump height of 0.3 mm, so some form of plastic underfilling can be used to protect the area between the die and the mounting substrate). Even more limiting, however, is the lack of physical isolation between the multiple contacts to the PC board and the bump material. This lack of isolation can cause problems with thermal mismatch over the operating temperature range of the die, between the dissimilar expansion/contraction coefficients of the silicon, ball/bump material, copper lands, and the soft solder mounting medium.

Two other disadvantages of “chip-scale” design are that the ball spacing (pitch) and ball size, have to accommodate the design rules of the PCB. These PCB design rules, however, are more often dictated by low cost, than by a desire to conform to the pitch of a particular die. Thus while the current standard for chip-scale balls is 0.3 mm diameter, forcing the die layout to obey external, PC board layout rules would reduce the efficient use of silicon area on the die, translating into increased costs.

Accordingly, there is a need in the art for semiconductor device packages making highly efficient use of available space, while offering many of the advantages of chip-scale packaging and allowing for multi-die assemblies.

### BRIEF SUMMARY OF THE INVENTION

Embodiments of the present invention relate to semiconductor device packages featuring encapsulated leadframes with projecting bumps or balls contacting a die supported thereon. By eliminating the need for a separate diepad and lateral isolation between an edge of the diepad and adjacent non-integral leads or pins, embodiments of packages in accordance with the present invention increase the space available to the die for a given package footprint. Embodiments of the present invention may also permit multiple die and/or multiple passive devices to occupy area previously consumed by the diepad. The result is a flexible packaging process allowing the combination of die and technologies required for complete sub-systems in a conventional small JEDEC specified footprint.

An embodiment of a package in accordance with the present invention, comprises, a die encapsulated within a plastic package body; and a leadframe including a lead bondpad in electrical communication with the die through an electrically conducting projection also encapsulated within the plastic package body, a portion of the lead bondpad overlapping the die.

An embodiment of a method of packaging a die in accordance with the present invention, comprises, providing a die in contact with an electrically conducting lead bondpad of a leadframe through an electrically conducting projection, and encapsulating the die and the lead bondpad within a plastic package body.

These and other embodiments of the present invention, as well as its features and some potential advantages are described in more detail in conjunction with the text below and attached figures.

### BRIEF DESCRIPTION OF THE DRAWINGS

FIG. 1 shows a simplified plan view of an example of a conventional package for a semiconductor device.

FIG. 2A shows a simplified perspective view (without injection molded plastic encapsulation) of an embodiment of a package in accordance with the present invention.

FIG. 2B shows a simplified cross-sectional view of the embodiment of the package of FIG. 2A.

FIG. 3A shows a simplified perspective view of an embodiment of a package in accordance with the present invention.

FIG. 3B shows a simplified cross-sectional view of the embodiment of the package of FIG. 3A.

FIG. 4A shows a simplified perspective view of an alternative embodiment of a package in accordance with the present invention.

FIG. 4B shows a simplified plan view of the embodiment of the package of FIG. 4A.

FIG. 4C shows a simplified cross-sectional view of the package of FIG. 4B taken along the line 4B-B′.

FIG. 5A shows a simplified plan view of another embodiment of a package in accordance with the present invention.

FIG. 5B shows a simplified cross-sectional view of the package of FIG. 5A taken along the line 5A-A′.

FIG. 6A shows a simplified plan view of another embodiment of a package in accordance with the present invention.

FIG. 6B shows a simplified cross-sectional view of the package of FIG. 6 A taken along the line 6C-C′.

FIG. 7A shows a simplified plan view of another embodiment of a package in accordance with the present invention.

FIG. 7B shows a simplified cross-sectional view of the package of FIG. 7A taken along the line 7A-A′.

FIG. 8A shows a simplified plan view of another embodiment of a package in accordance with the present invention.

FIG. 8B shows a simplified cross-sectional view of the package of FIG. 8A taken along the line 8C-C′.

FIG. 9A shows a simplified plan view of another embodiment of a package in accordance with the present invention.

FIG. 9B shows a simplified cross-sectional view of the package of FIG. 9A taken along the line 9A-A′.

FIG. 10A shows a simplified plan view of another embodiment of a package in accordance with the present invention.

FIG. 10B shows a simplified cross-sectional view of the package of FIG. 10A taken along the line 10M-M′.

FIG. 11A shows a simplified perspective view of an alternative embodiment of a package in accordance with the present invention.

FIG. 11B shows a simplified plan view of the embodiment of the package of FIG. 11A.

FIG. 11C shows a simplified cross-sectional view of the package of FIG. 4B taken along the line 11B-B′.

FIG. 12A shows a simplified plan view of the embodiment of a package in accordance with the present invention.

FIG. 12B shows a simplified cross-sectional view of the package of FIG. 12A taken along the line 12A-A′.

FIG. 12C shows a simplified cross-sectional view of the package of FIG. 12A taken along the line 12B-B′.

FIG. 13A shows a simplified plan view of the embodiment of a package in accordance with the present invention.

FIG. 13B shows a simplified cross-sectional view of the package of FIG. 13A taken along the line 13B-B′.

FIG. 13C shows a simplified cross-sectional view of the package of FIG. 13A taken along the line 13A-A′.

### DETAILED DESCRIPTION OF THE INVENTION

Embodiments of the present invention relate to semiconductor device packages featuring encapsulated leadframes with projecting bumps or balls contacting a die supported thereon. By eliminating the need for a separate diepad and lateral isolation between an edge of the diepad and adjacent non-integral leads or pins, embodiments of packages in accordance with the present invention increase the space available to the die for a given package footprint. Embodiments of the present invention may also permit multiple die and/or multiple passive devices to occupy area previously consumed by the diepad. The result is a flexible packaging process allowing the combination of die and technologies required for complete sub-systems in a conventional small JEDEC specified footprint.

Embodiments in accordance with the present invention use balls or bumps in contact with a die, in a manner similar to chip-scale packages having a lead directly supporting a die, without the die being attached to a diepad portion of a leadframe as in conventional leaded packages. Encapsulation avoids exposing the die to the environment, which eliminates the need for a costly process to fill in regions between the die and lead bondpad. Embodiments in accordance with the present invention also allow the die layout to be compacted in accordance with the die design rules, rather than having to conform to chip-scale design rules requiring pad pitch that can be directly attached to the PCB, often at the expense of die size.

One difference between a die packaged in accordance with an embodiment of the present invention and a “chip-scale” die, is that the pad spacing on the die does not have to be arranged to meet PCB layout rules. In addition, the balls or bumps used for the attachment and electrical signals do not have to conform to JEDEC registered pitch and height requirements. In fact, when mounted to a leadframe and encapsulated, it becomes desirable to reduce the bump/ball height to a fraction of that used when directly to a PCB.

Embodiments in accordance with the present invention allow the balls/bumps to be smaller than with traditional chip-scale packaging, which permits smaller contact pads on the die, further contributing to reduction in die size. Using lower profile bumps inside the package allows a slightly larger die in a given package, and also enables multiple die to be stacked without increasing the package height.

The ball or bumps of embodiments in accordance with the present invention may provide a larger diameter and shorter electrical and thermal bond than conventional bond wires This results in low electrical and thermal resistance between the die and package leads, while adding less stray inductance and capacitance than conventional bondwires having a round cross-sectional profile.

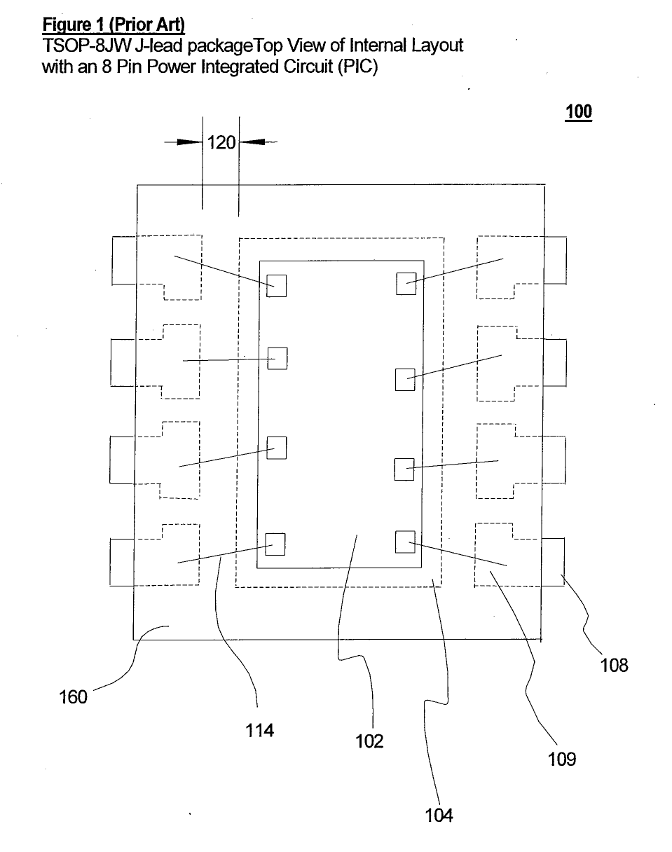

As illustrated in the top view of the conventional bond wired J-lead die assembly shown in FIG. 1, on each side the diepad 104 is isolated from the lead bondpads 109 of the leads 108 by an isolation area 120. This isolation area does not decrease as the package size decreases, which means it occupies a larger percentage of the footprint as the package size is reduced.

By contrast, in a package having the same outside dimensions as FIG. 1 but utilizing the Bump On Leadframe (BOL) assembly process in accordance with an embodiment of the present invention, the size of the die housed in the existing footprint of any package may be increased by as much as two-fold in the smallest, commonly available, J-lead packages. Specifically, embodiments of packages in accordance with the present invention obviate the need for the wasted space between the diepad and the bond posts on the leads, that is otherwise consumed to isolate the separate pins when using conventional bond wired connections to the die. Furthermore, the BOL attachment in accordance with embodiments of the present invention allows the die to overlap the “bonding header” portion of the leads, which further increases the maximum die size/package footprint efficiency.

Various embodiments of package designs in accordance with the present invention are illustrated in the following figures. In certain figures, the plastic package body encapsulating the die may be shown in outline or omitted entirely, for ease of illustration.

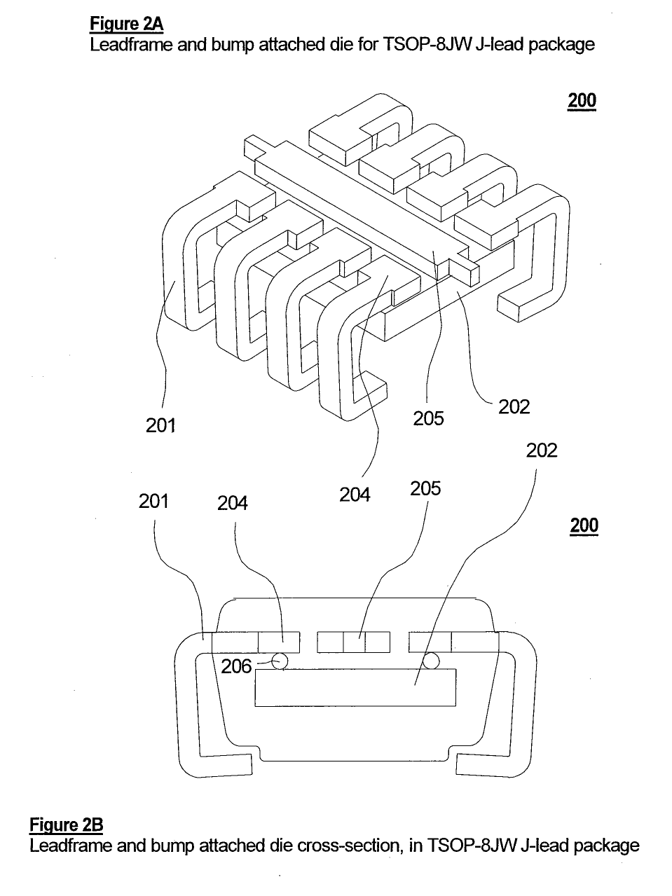

FIG. 2A shows a simplified perspective view of an embodiment of a package in accordance with the present invention. FIG. 2B shows a simplified cross-sectional view of the embodiment of the package of FIG. 2A. The plastic injected molded package body has been omitted from FIG. 2A for clarity of illustration. In the package 200 utilizing the BOL die/leadframe arrangement shown in FIGS. 2A-B, the die 202 and lead bondpads 204 of leads 201 overlap, and the electrical connection is made vertically via the bump or ball 206.

In the configuration shown in FIGS. 2A-B, the matrix tie-bar 205 is used to connect the encapsulated package to the leadframe matrix (not shown in FIGS. 2A-B) during the lead trim and form steps. As described below and shown in subsequent figures, in other embodiments the tie-bar may exhibit additional functions, such as signal routing and in more complex die arrangements demonstrated, as a conventional diepad.

Utilization of a Bump On Leadframe (BOL) process in accordance with an embodiment of the present invention in conjunction with a J-lead package design, can produce a package wherein the die occupies as much as 85% of the package footprint. Moreover, adopting the outside form (i.e. reverse-gull wing lead shape and body notches) and dimensions of the J-lead style package illustrated in cross-section in FIG. 2B, minimizes the height and footprint penalty and provides certain benefits as indicated above, plus the opportunity to encapsulate multi-die and multi-technology die in a low electrical and thermal resistance package that adds minimal stray inductance and capacitance.

In the conventional chip-scale approach, by definition the die occupies 100% of the footprint. However, the size of the die may be affected by the need to modify the die design rules to meet external layout rules. By contrast, utilizing embodiments of packaging techniques in accordance with the present invention, the leadframe can serve as an intermediary to translate between optimized design rules of the die and of the PCB, so that the optimized design rules of the PCB are not adversely impacted.

Moreover, embodiments in accordance with the present invention may also provide electrical routing options or other components or features that open up additional functional possibilities for the packages. For example, in the specific embodiment depicted in FIGS. 2A-B, the tie-bar is not electrically connected with the die, and provides purely mechanical support for the encapsulated package during lead trimming from the matrix and J-lead forming, without performing any electrical function.

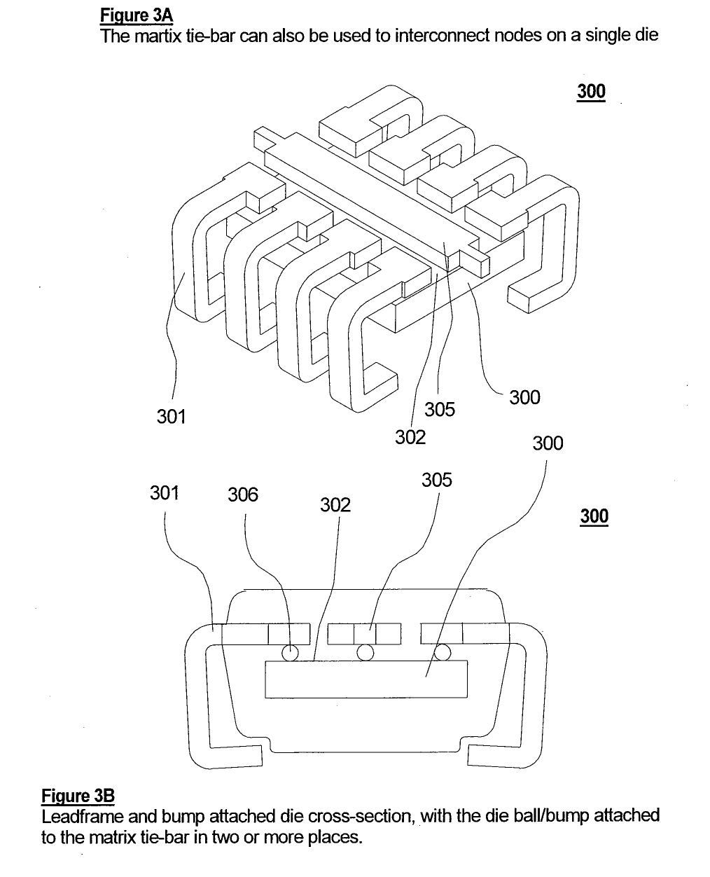

By contrast, in the alternative embodiment of the present invention shown and described in FIGS. 3A-B, the matrix tie-bar performs an electrical function. Specifically, FIG. 3A shows a simplified perspective view of an alternative embodiment of a package 300 in accordance with the present invention. FIG. 3B shows a simplified cross-sectional view of the embodiment of the package of FIG. 3A. Again, for purposes of illustration the plastic injected molded package body has been omitted from FIG. 3A.

In the embodiment of FIGS. 3A-B, tie-bar 305 becomes a shorting bar for two or more electrical nodes located on the surface 302 of the die 300. Balls or bumps 306 are then used to connect the input, output and power nodes to the leads 301 around the periphery of the die. Whether the matrix of leadframes are formed by stamping or by etching, the matrix tie-bar is inherently co-planar with the leads, and therefore, the balls or bumps of the same height are readily attached to the planar lead bond headers and to the tie-bar.

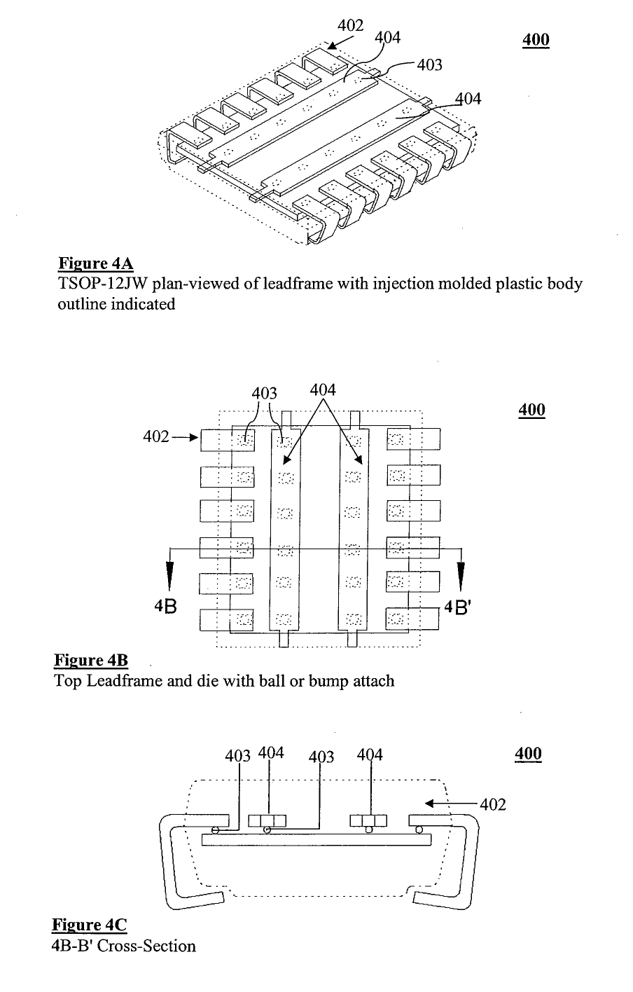

While the present invention has been illustrated so far in conjunction with a package having a single tie-bar, embodiments in accordance with the present invention are not so limited. For example, FIG. 4A shows a simplified perspective view of an alternative embodiment of a package 400 in accordance with the present invention. FIG. 4B shows a simplified plan view of the embodiment of the package of FIG. 4A. FIG. 4C shows a simplified cross-sectional view of the package of FIG. 4B taken along the line 4B-B′. In these and all subsequent figures, the outline of the plastic package body is shown in dashed lines for ease of illustration.

This TSOP-12JW package 400 with a 12 leadframe 402 illustrates that the bump 403 on leadframe (BOL) processes in accordance with embodiments of the present invention, are applicable to fabricating a number of leaded and leadless packages, without changing the external dimensions of the package. Such embodiments may improve the die size, the bond wire resistance, and the thermal performance of most standard bond wired products. In the specific embodiment of FIGS. 4A-C, the matrix tie-bars have been separated into two separate bars 404. The two matrix tie-bars can be used to interconnect two separate electrical nodes.

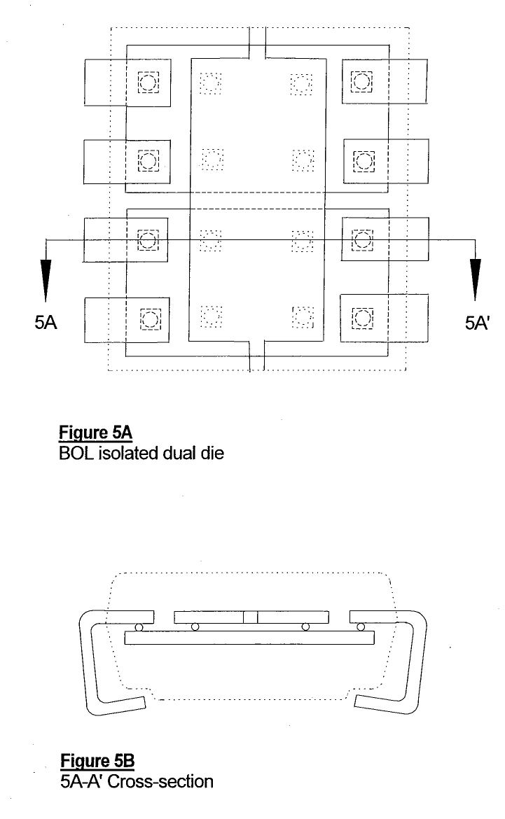

FIG. 5A shows a simplified plan view of another embodiment of a package in accordance with the present invention. FIG. 5B shows a simplified cross-sectional view of the package of FIG. 5A taken along the line 5A-A′. In the package 500 shown in FIGS. 5A-B, two die 502 and 504 attached by bump or ball 506 on one side of the leadframe 508 and interconnected by BOL attachment to a common center pad/matrix tie-bar 510.

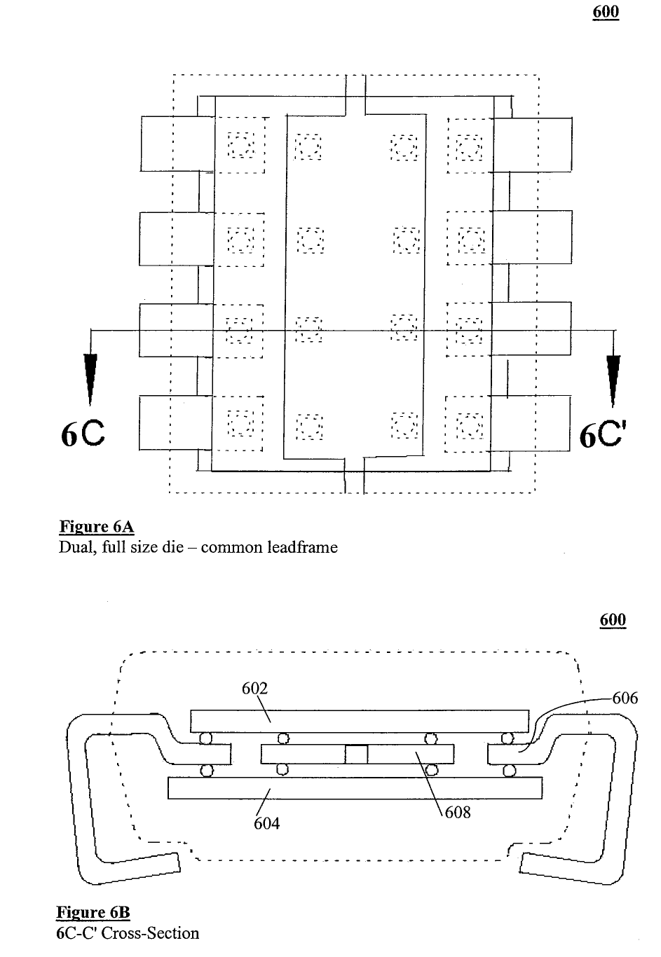

FIG. 6A shows a simplified plan view of yet another embodiment of a package in accordance with the present invention. FIG. 6B shows a simplified cross-sectional view of the package of FIG. 6A taken along the line 6C-C′. In package 600 shown in FIGS. 6A-B, another dual die arrangement is illustrated. Specifically, in this embodiment, the die 602 and 604 are BOL attached to both sides of the leadframe 606, and to each side of the common center pad/matrix tie-bar 608. Here, the BOL processes used to attach each of the die 602 and 604 differ in attachment temperature, so that the first die will not be degraded during attachment of the second die. For example, the first die can be attached using Gold balls formed from thermosonic welding, and the second die can utilize bumps preformed on the die and attached to the leadframe using soft solder reflow (a lower temperature process).

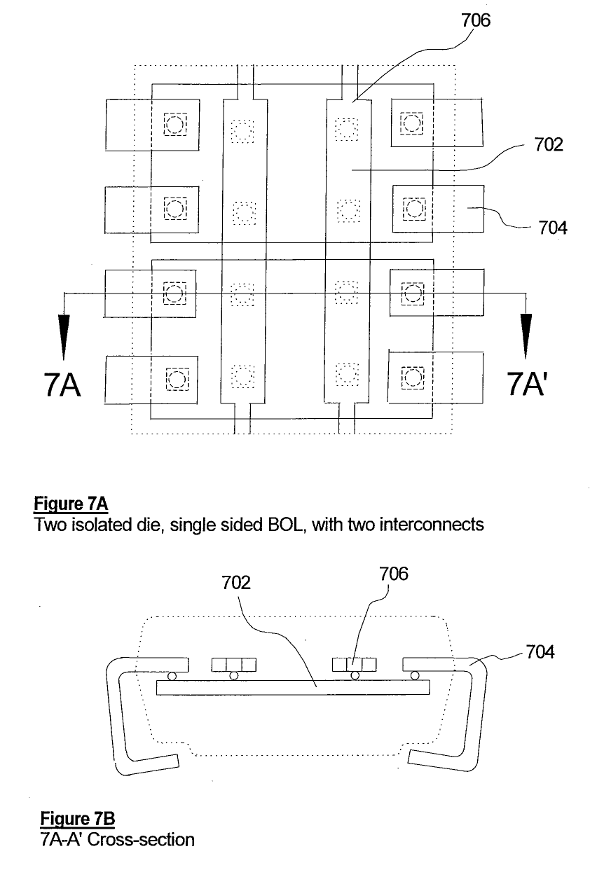

FIG. 7A shows a simplified plan view of still another embodiment of a package in accordance with the present invention. FIG. 7B shows a simplified cross-sectional view of the package of FIG. 7A taken along the line 7A-A′. In this arrangement of package 700, the two die 702 can be attached simultaneously to the leads 704, and to matrix tie-bars 706 interconnecting electrical nodes on the die 702.

Most two die package products are dual versions housing two of the same die. In the embodiment of FIGS. 7A-B, the multiple die package configuration may include two identical die or two different die.

Moreover, the embodiment of FIGS. 7A-B may also allow die of two different technologies to be used. For example, the low impedance and low stray inductance interconnect provided by the matrix tie-bars can be of particular advantage for certain products like a very high speed pulse width modulated (PWM) die driving a very high speed discrete die, such as a DMOS lateral or similar technology. Such package applications have drive new die arrangements and assembly methods featuring a low impedance interconnect between two die and very low stray inductance. PWM frequencies will soon be high enough frequencies to reduce the size of the passive components—capacitors and inductors used to filter the PWM pulses back to a clean DC voltage. At the same time, however, those high frequencies will eliminate the possibility of packaging the die separately and interconnecting them on a PCB. Embodiments in accordance with the present invention resolve this problem.

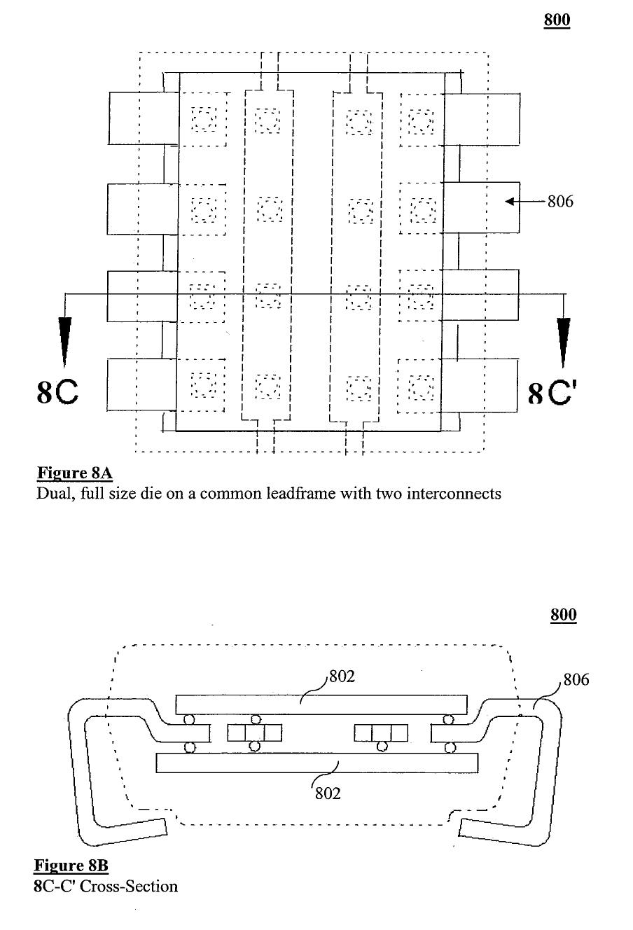

FIG. 8A shows a simplified plan view of a still more complex package configuration in accordance with an embodiment of the present invention. FIG. 8B shows a simplified cross-sectional view of the package 800 of FIG. 8A taken along the line 8C-C′. The alternative embodiment of FIGS. 8A-B accommodates two full sized die 802 in the same package footprint. The number of leads 806 in these J-lead packages can range from 6 to 14, and this approach confers the ability to produce a dual die package occupying a PC Board footprint no larger than the single die package. For example, in several products like Low (voltage) Drop Out regulators (LDOs), two or more die are often used together, with the only difference between them being the voltage they are programmed to output. In such applications, a dual die package in accordance with an embodiment of the present invention can conveniently be configured to have all pins on the two die tied common, except for the die outputs that are brought out on separate leads.

As long as the die are packaged during processes running on existing assembly lines, matrix tie-bars will likely be used to allow automated handling of the packages in the matrix state following trim-and-form steps. These tie-bars, however, need not occupy space that could otherwise be allocated to active die or passive package components.

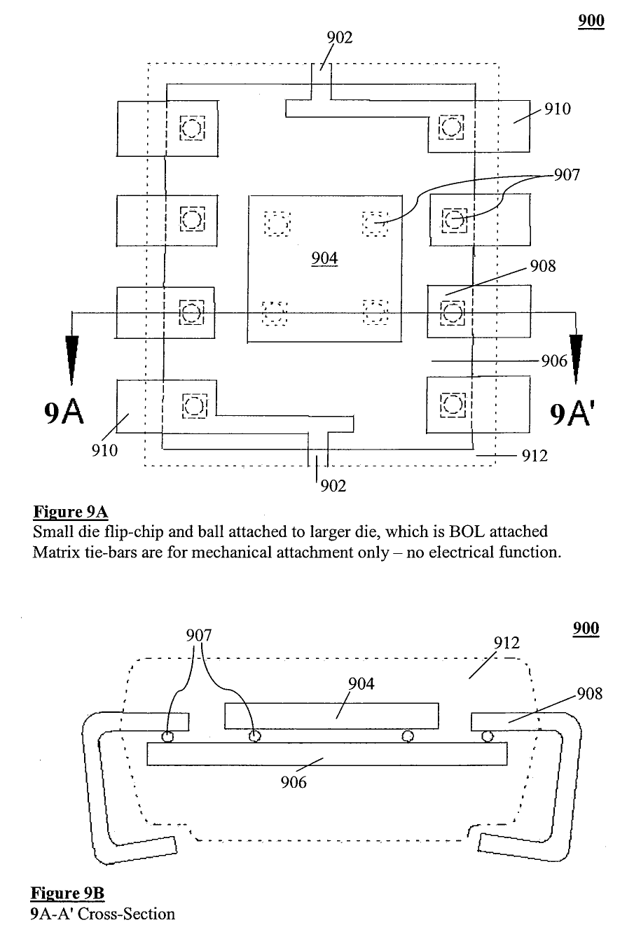

For example, FIG. 9A shows a simplified plan view of another embodiment of a package 900 in accordance with the present invention. FIG. 9B shows a simplified cross-sectional view of the package of FIG. 9A taken along the line 9A-A′. Package 900 of FIGS. 9A and B offers the option not use the matrix tie-bars 902 for any electrical function. Specifically, small die 904 is attached to the larger die 906 using either a higher temperature solder reflow, or a thermosonic welded ball process, and then the two die 904 and 906 are bump or ball 907 attached to the leadframe 908 using a lower temperature solder reflow process. In the particular embodiment of FIGS. 9A-B, the matrix tie-bars 902 are integral with leads 910 anchored in the injection molded plastic 912.

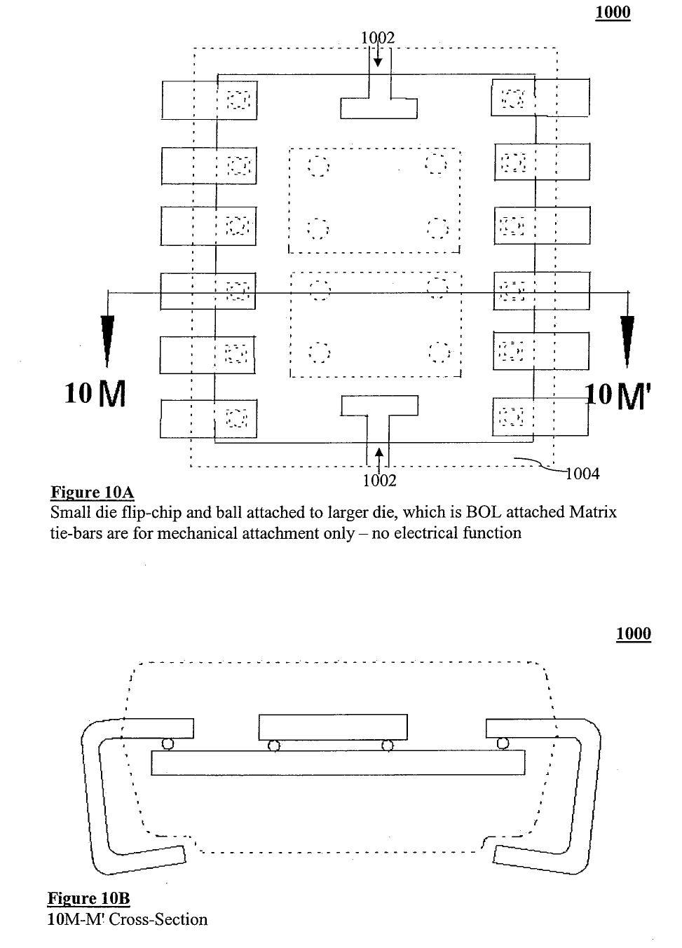

FIG. 10A shows a simplified plan view of another embodiment of a package 1000 in accordance with the present invention. FIG. 10B shows a simplified cross-sectional view of the package of FIG. 10A taken along the line 10M-M′. Package 1000 of the embodiment of FIGS. 10A and B illustrates the same type of multi-die assembly as with the embodiment shown in FIGS. 9A-B, but with a higher pin-count package. In the particular embodiment of FIGS. 10A-B, the matrix tie-bars 1002 are anchored in the injection molded plastic 1004.

Assembly methods and arrangements demonstrated in the previous embodiments can be used in the J-Quad packages. Moreover, the extra space and pins provided by J-Quad packages may allow them to also exhibit other features.

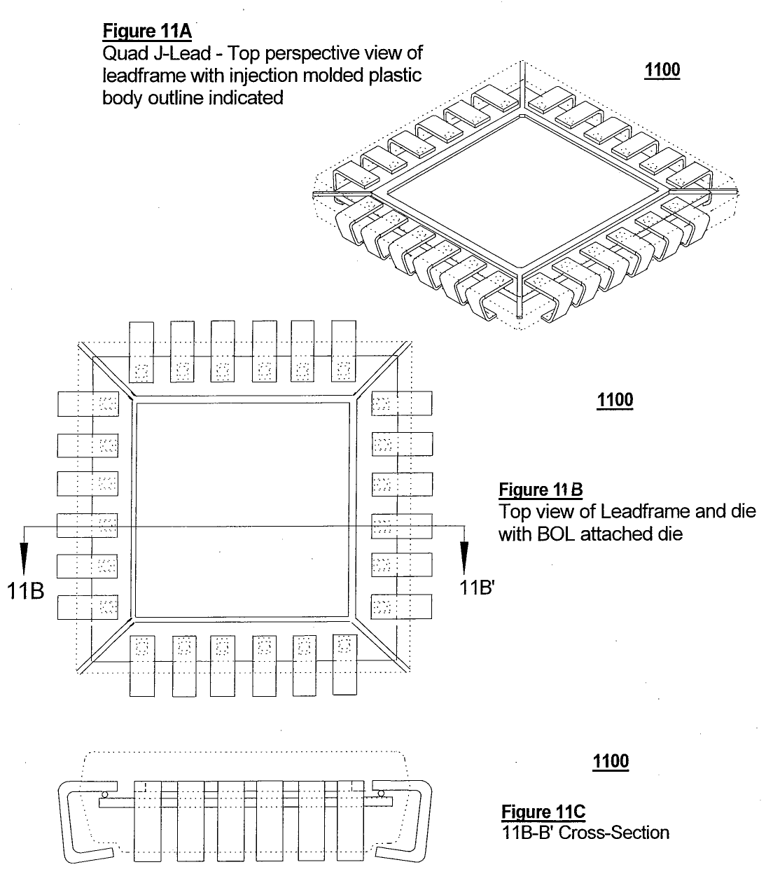

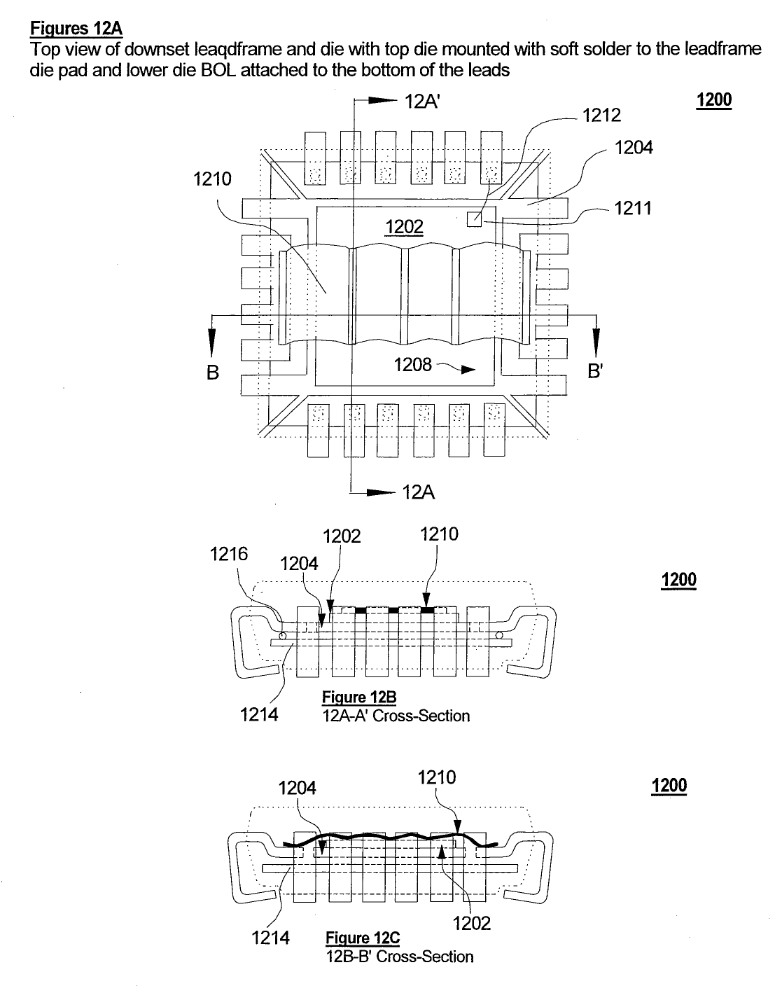

For example, FIG. 11A shows a simplified perspective view of an alternative embodiment of a package 1100 in accordance with the present invention. FIG. 11B shows a simplified plan view of the embodiment of the package of FIG. 11A. FIG. 11C shows a simplified cross-sectional view of the package of FIG. 11B taken along the line 11B-B′. FIGS. 11A-C demonstrate an embodiment of another series of small J-lead packages offering a wider range of pin-count and a variety of die size options. In FIG. 11A, a 4×4 mm Quad-24J package 1100 demonstrates a simple, single die, arrangement.

Conventional bondwired quads have matrix tie-bars at each of the four corners to support the diepad during die bonding and wire bonding, and to support the package after encapsulation, during the lead trim and form process steps. As shown in the J-lead example of FIGS. 11A-C, the BOL version of the Quad J-lead package may maintain the same convention. In such embodiments, the matrix tie-bars are not supporting a conventional diepad, but rather an open square. The open structure of the embodiment of FIGS. 11A-C may allow molding compound to flow more evenly to cover the top of the die that is BOL mounted in accordance with an embodiment of the present invention.

In the embodiment shown in FIGS. 11A-C, not providing a conventional diepad also creates area where one or more secondary die could be directly attached to the primary die using a redistribution metal layer to form die mount pads on the primary die. Such die mount pads could accommodate the bumped secondary die as shown in the embodiment of FIGS. 10A-B.

While embodiments described so far have avoided a conventional diepad element, this is not required by the present invention. Inclusion of a diepad opens a number of possible packaging arrangements combining BOL attached die, with die having electrical connection to both sides (such as the vertical conduction DMOS die), or for other reasons require flexible bonding to make up for variable die thicknesses.

For example, FIG. 12A shows a simplified plan view of an alternative embodiment of a package in accordance with the present invention. FIG. 12B shows a simplified cross-sectional view of the package of FIG. 12A taken along the line 12A-A′. FIG. 12C shows a simplified cross-sectional view of the package of FIG. 12A taken along the line 12B-B′.

The embodiment of FIGS. 12A-C shows the more complex die combinations that can be realized with the larger package pin counts and the additional die space afforded by Quad-type packages. Specifically, in package 1200 of FIGS. 12A-C, the top die is a Mosfet 1202, which is attached to a down-set diepad 1204 as with a conventional Quad J-lead product. Electrical communication with Gate contact 1211 of the Mosfet is established using a conventional 5 mil Aluminum bond wire 1212, and electrical communication with Source contact 1208 of the Mosfet is established using low profile Aluminum ribbon bonding 1210. Co-pending U.S. patent application Ser. No. 11/559,819, filed Nov. 14, 2006, describes such ribbon bonding in detail and is incorporated by reference in its entirety herein for all purposes.

Having completed this die attachment, the matrix is inverted and the lower die 1214 is attached to bump 1216 using a lower temperature BOL attachment technique in accordance with an embodiment of the present invention. As in previous BOL attachments, the BOL attached die is not in contact with the diepad which supports the Mosfet. In this case, the diepad and lower die form two large plates that molding compound must fill between, without voids, during the injection molding process. For this reason, the bumps or balls chosen for this BOL attachment will be sized larger to make more room for the plastic to flow between.

The packaging of more complex die stacks in accordance with embodiments of the present invention may require additional consideration regarding the sequence of attachment and the technology used for such attachment. The multi-die arrangements described so far may use soft-solder compounds designed to have compatible reflow temperatures, so each step in the process will not degrade previous steps.

There are a number of technologies that can produce a reliable bump or ball attachment, as well as a range of reflow temperatures for soft solder. Offering promise among these technologies are those drawing on knowledge and equipment previously used to ball bond Gold and Copper wire. In such cases, a thermosonic welding process is used to create the ball bond, and the wire is then simply cut off. This can be used to create balls on an entire wafer surface while still in the wafer form, or on the leadframe. The second attachment can then be a conventional soft solder reflow for the die with Gold or Copper balls formed on their contacts. Alternatively, a die can be flip-chip placed atop balls formed on the leadframe, and a second thermosonic bond can attach all of the balls to the die simultaneously. Presently, this option only exists for die with a limited number of ball attachments. However, thermosonic bonding provides a useful tool as it is a welding process and quite impervious to subsequent soft solder temperatures. Accordingly, an objective in accordance with the present invention is to select each attachment process so it will not degrade previous processes, and which will be compatible with the electrical requirements of the product.

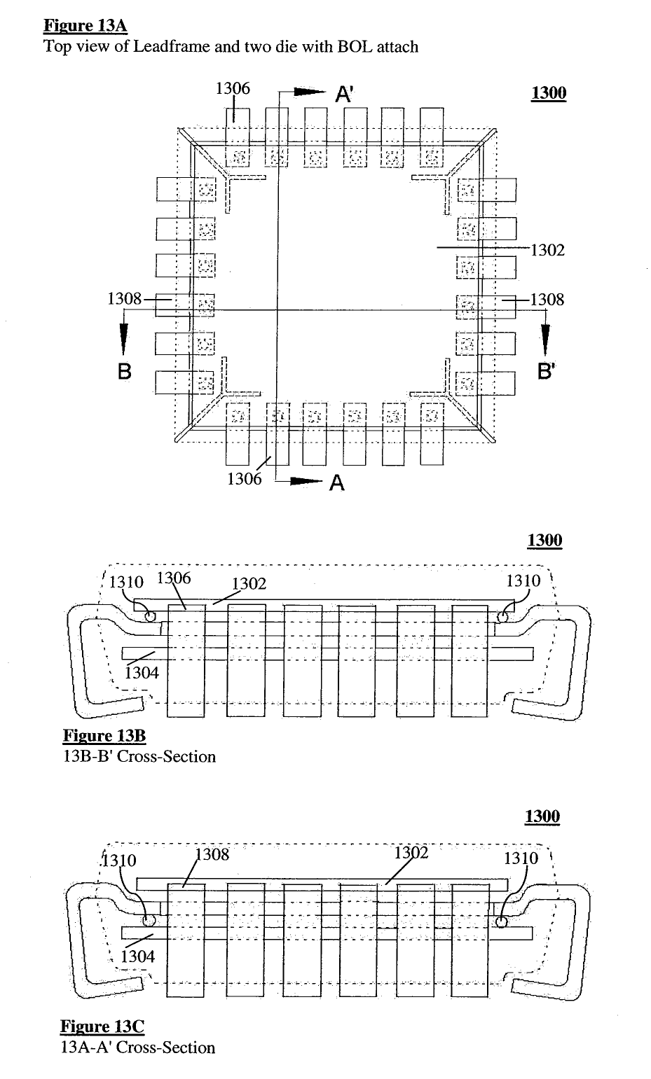

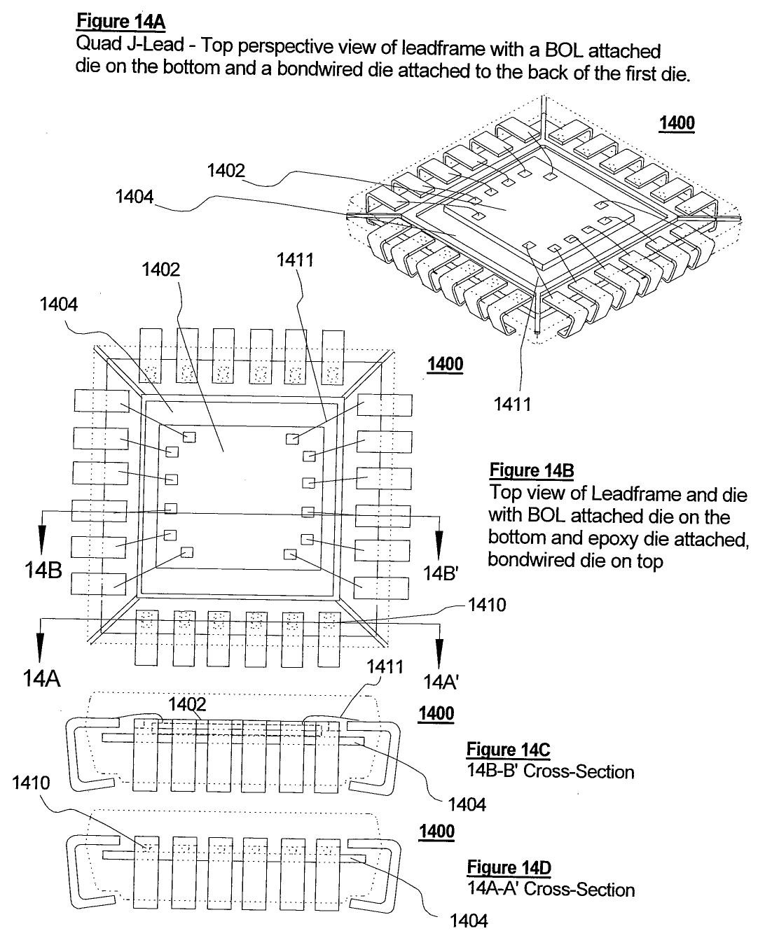

FIG. 13A shows a simplified plan view of another alternative embodiment of a complex, multi-die package 1300 in accordance with the present invention. FIG. 13B shows a simplified cross-sectional view of the package of FIG. 13A taken along the line 13B-B′. FIG. 13C shows a simplified cross-sectional view of the package of FIG. 13A taken along the line 13A-A′. Package 1300 of FIGS. 13A-C represents a dual die BOL arrangement in accordance with the present invention, similar to that employed in the previous embodiments, except that each of the two packaged die 1302 and 1304 are in electrical communication with lead bondpads 1306 and 1308, respectively, for BOL attachment, with conducting bumps or balls 1310 positioned at opposite ends. As a result, the quad package shown in FIGS. 13A-C becomes, in essence, two packages in a single footprint, with two separate die 1302 and 1304 oriented at 90° with respect to one another. In the arrangement shown in FIGS. 13A-C, space is conserved and the die are separate and independent, with no required electrical or functional relationship.

FIG. 14A shows a simplified plan view of another alternative embodiment of a complex, multi-die package 1400 in accordance with the present invention. FIG. 14B shows a simplified cross-sectional view of the package of FIG. 14A taken along the line 14A-A′. FIG. 14C shows a simplified cross-sectional view of the package of FIG. 14A taken along the line 14B-B′. Package 1400 of FIGS. 14A-C represents a dual die BOL arrangement similar to that employed in the previous embodiments, except that die 1404 has lead bondpads for BOL attachment with conducting bumps or balls 1410 positioned at opposite ends. The second die 1402 is flip-chip mounted on the back of die 1404 using epoxy die attach material.

Electrical contacts to the second die 1402 are established through conventional 2 mil Gold bondwires attached 1404 to each contact pad on the die and to each of the leads on the two sides not used for BOL attachment of 1404 die. In the arrangement of FIGS. 14A-C, space is conserved and the die are electrically separate and independent if an electrically insulating epoxy is used for the attachment of die 1402 to die 1404. If a conductive (i.e. silver doped) epoxy is used to attach die 1402 to die 1404, then die 1402 and 1404 will share a common substrate connection on the back side of both.

While the above description has focused so far on the fabrication of leaded packages, the present invention is not limited to this particular package type. BOL techniques in accordance with alternative embodiments of the present invention are also applicable to the fabrication of other types of packages, including those having external connections in the form of pins, and “leadless” packages such as QFNs, DFNs, SON, and PowerPAK packages. In order to encompass such alternative embodiments, as used herein the terms “lead” and “lead bondpad” is understood to refer to any electrically conducting element that extends out of the package body to establish electrical communication with die housed therein.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A package comprising:
a die encapsulated within a plastic package body; and
a leadframe including a lead bondpad in electrical communication with the die through an electrically conducting projection also encapsulated within the plastic package body, a portion of the lead bondpad overlapping the die.

2. The package of claim 1 wherein the projection comprises a bump or a ball extending from the die surface.

3. The package of claim 1 wherein the projection comprises a bump or ball extending from the bondpad.

4. The package of claim 1 wherein the projection comprises a solder ball.

5. The package of claim 1 wherein the projection comprises a thermosonic welded ball.

6. The package of claim 1 wherein the leadframe further comprises a tie-bar overlapping the die.

7. The package of claim 6 further comprising a second electrically conducting projection also encapsulated within the plastic package body and allowing electrical communication between the tie-bar and the die.

8. The package of claim 1 further comprising a second die.

9. The package of claim 8 wherein the second die is supported by the die on an electrically conducting projection.

10. The package of claim 8 wherein the leadframe further comprises a second lead bondpad in electrical communication with the second die through an electrically conducting second projection also encapsulated within the plastic package body, a portion of the second lead bondpad overlapping the second die.

11. The package of claim 8 further comprising a tie-bar overlapping the die and the second die.

12. The package of claim 11 wherein the die and the second die are located on a same side of the tie-bar.

13. The package of claim 11 wherein the die and the second die are located on opposite sides of the tie-bar.

14. The package of claim 11 wherein the die and the second die are in electrical communication with the tie-bar through additional electrically conducting projections.

15. The package of claim 8 wherein the second die is supported on a diepad.

16. A method of packaging a die, the method comprising:
providing a die in contact with an electrically conducting lead bondpad of a leadframe through an electrically conducting projection; and
encapsulating the die and the lead bondpad within a plastic package body.

17. The method of claim 16 wherein a lead integral with the lead bondpad extends outside of the plastic package body.

18. The method of claim 16 wherein the die is provided with the electrically conducting projection.

19. The method of claim 16 wherein the leadframe is provided with the electrically conducting projection.

20. The method of claim 16 wherein the leadframe is further provided with a tie-bar overlapping the die.
